(19) United States
(12) Patent Application Publication
(10) Pub. No.: US 2026/0333720 A1
(43) Pub. Date: Oct. 22, 2026

(54) MECHANICAL BARRIER UNDER A THREE-DIMENSIONAL (3D) CAPACITOR

(71) Applicant: STMicroelectronics International N.V., Geneva (CH)

(72) Inventors: Ludovic DUPRE, Crolles (FR); Marios BARLAS, Grenoble (FR); Hugo NUEZ, Grenoble (FR); Yannick LE FRIEC, Goncelin (FR); Magali GREGOIRE, Crolles (FR)

(73) Assignee: STMicroelectronics International N.V., Geneva (CH)

(21) Appl. No.: 19/185,830

(22) Filed: Apr. 22, 2025

(30) Foreign Application Priority Data
Apr. 24, 2024 (GR) 20240100298
Aug. 13, 2024 (FR) FR2408899

(51) Int. Cl. H10D 1/68

(52) U.S. Cl. CPC H10D 1/716

(57) ABSTRACT

An electronic device includes a copper pad and a dielectric layer formed on the copper pad. A trench extends through the dielectric layer to emerge onto the copper pad. A metal layer is provided on side flanks and at a bottom of the trench. A conductive layer forms an interface between the copper pad and the metal layer at the bottom of the trench. The conductive layer is in contact, by its lower surface, with the upper surface of the copper pad, and is in contact, by its upper surface, with the lower surface of the metal layer.

### PRIORITY CLAIM

This application claims the priority benefit of Greece Application for Patent No. 20240100298 filed Apr. 24, 2024, and claims the priority benefit of French Application for Patent No. FR2408899 filed on Aug. 13, 2024, the contents of which are hereby incorporated by reference in their entirety to the maximum extent allowable by law.

### TECHNICAL FIELD

The present disclosure generally concerns electronic devices and, in particular, electronic devices of three-dimensional (3D) capacitor type and their manufacturing methods.

### BACKGROUND

A capacitor comprises a succession of three layers and more specifically comprises an insulating layer between two conductive layers. In a three-dimensional capacitor, these three layers are formed on the side flanks of a trench formed in a dielectric layer. The capacitance of such a capacitor then depends on the depth and on the width of the trench on the side flanks of which the capacitor layers extend.

It would be desirable to at least partly improve certain aspects of such devices.

### SUMMARY

In an embodiment, an electronic device comprises: at least one copper pad; a dielectric layer formed on the copper pad, the dielectric layer comprising a trench emerging onto the copper pad; a metal layer on the side flanks and at the bottom of the trench; and a conductive layer forming an interface between the copper pad and the metal layer at the bottom of the trench, the conductive layer being in contact, by its lower surface, with the upper surface of the copper pad, and, by its upper surface, with the lower surface of the metal layer.

According to an embodiment, the conductive layer has a thickness less than 20 nm.

According to an embodiment, the metal layer is made of titanium silicon nitride and the conductive layer is made of a selected one of: titanium nitride, tantalum, tantalum nitride, or a tantalum nitride and tantalum bilayer.

According to an embodiment, the metal layer corresponds to an electrode of a three-dimensional capacitor.

According to an embodiment, the capacitor is a metal-insulator-metal capacitor, the metal layer being topped with another dielectric layer, itself topped with another metal layer, the other dielectric layer being in contact, by its lower surface, with the metal layer, and being in contact, by its upper surface, with the other metal layer.

According to an embodiment, the conductive layer entirely covers the copper pad exposed at the bottom of the trench.

According to an embodiment, the dielectric layer is separated from the copper pad by a nitride passivation layer.

Another embodiment provides a method of manufacturing an electronic device, comprising the successive steps of: depositing a conductive layer at the bottom of a trench formed in a dielectric layer, the trench emerging onto a copper pad; and depositing a metal layer on the side flanks and at the bottom of the trench, the conductive layer forming an interface between the copper pad and the metal layer, the conductive layer being in contact, by its lower surface, with the upper surface of the copper pad, and, by its upper surface, with the lower surface of the metal layer.

According to an embodiment, the conductive layer has a thickness less than 20 nm.

According to an embodiment, the metal layer is deposited by an atomic layer deposition (ALD) method and the conductive layer is deposited by a physical vapor deposition (PVD) method or a chemical vapor deposition (CVD) method.

According to an embodiment, during the deposition of the conductive layer, the latter is further deposited on the side flanks of the trench.

According to an embodiment, the conductive layer is deposited within less than two minutes.

According to an embodiment, the conductive layer is deposited at a temperature less than 200 ° C.

According to an embodiment, the conductive layer is deposited within less than two minutes and at a temperature less than 200 ° C.

According to an embodiment, the trench is further formed in a passivation layer between the dielectric layer and the copper pad.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a cross-section view, partial and simplified, of an example of an electronic device;

FIG. 2 is a cross-section view, partial and simplified, of an example of an electronic device; and

FIGS. 3A to 3F are cross-section views of a structure obtained at the end of a step of a method of manufacturing the electronic device illustrated in FIG. 2.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

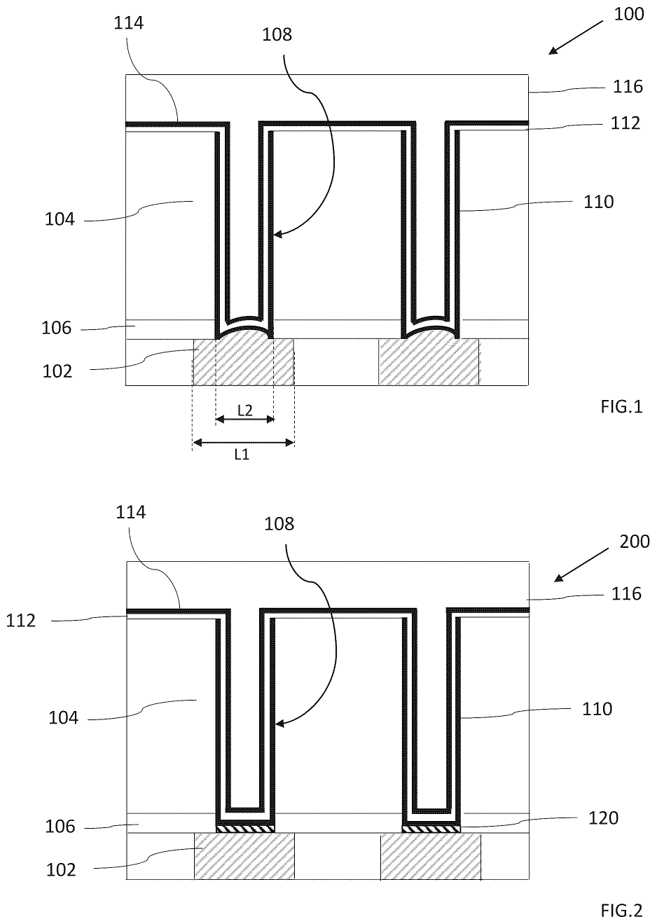

FIG. 1 is a cross-section view, partial and simplified, of an example of an electronic device 100.

Electronic device 100 corresponds, for example, to a portion of an image sensor manufactured in complementary metal oxide semiconductor (CMOS) technology.

Electronic device 100 may, as a variant, correspond to a portion of a memory comprising a plurality of memory cells.

Electronic device 100 comprises a plurality of copper metal pads 102.

Copper pads 102 extend, in the cross-section plane of FIG. 1, for example across a width L1 in the range from 80 nm to 12 μm, for example, across a width L1 in the order of 130 nm.

As an example, copper pads 102, extend, orthogonally to the cross-section plane of FIG. 1, along a length in the range from 80 nm to several millimeters, for example along a length in the order of 2 μm.

As an example, copper pads 102 are laterally surrounded by a layer made of a dielectric material.

The copper pads are, for example, topped with a dielectric layer 104. As an example, dielectric layer 104 extends over all the copper pads 102. Dielectric layer 104 is, for example, an oxide or nitride layer. As an example, dielectric layer 104 is made of silicon dioxide and/or of silicon carbon nitride and/or of undoped silicon glass (USG). As an example, dielectric layer 104 has a thickness in the range from 700 nm to 2 μm, for example a thickness in the order of 1 μm.

As an example, the copper pads 102 are separated from dielectric layer 104 by an insulating layer 106. As an example, layer 106 is in contact, by its lower surface, with the upper surface of copper pads 102 and in contact, by its upper surface, with the lower surface of dielectric layer 104. For example, layer 106 is made of a nitride, for example made of silicon nitride. As an example, dielectric layer 106 has a thickness in the range from 10 nm to 100 nm, for example a thickness in the order of 50 nm.

Electronic device 100 comprises, in dielectric layer 104, trenches 108 emerging onto copper pads 102. As an example, trenches 108 are through trenches and extend from an upper surface of dielectric layer 104 to a lower surface of dielectric layer 104. As an example, trenches 108 further run through layer 106 from its upper surface to its lower surface. As an example, trenches 108 extend, in dielectric layer 104, and for example in layer 106, vertically in line with copper pads 102. As an example, trenches 108 are formed in dielectric layer 104 so that a trench 104 faces a copper pad 102.

As an example, trenches 108 extend, in the cross-section plane of FIG. 1, across a width L2. Trenches 108 have, for example, an aspect ratio, corresponding to the ratio of their depth to their width, in the range from 4 to 10, including 4 and 10. As an example, trenches 108 have an aspect ratio in the order of 7. Trenches 108 are, for example, elliptical cylinders.

As an example, the width L2 of trenches 108 is smaller than or equal to the width L1 of copper pads 102. As an example, width L2 is in a range from 80 nm to 160 nm, for example in the order of 130 nm.

As an example, trenches 108 extend, orthogonally to the cross-section plane of FIG. 1, along at least part of the length of copper pads 102. In this example, trenches 108 extend orthogonally to the cross-section plane of FIG. 1, along a length in the range from 80 nm to several micrometers, for example a length in the range from 80 nm to 1 μm, for example a length in the order of 250 nm.

As a variant, trenches 108 correspond to cylindrical openings or fingers organized, in top view, in an array of rows and of columns, the openings of a same row being formed vertically in line with a same copper pad 102.

Electronic device 100 comprises a metal layer 110 coating the side flanks and the bottom of trenches 108. As an example, metal layer 110 is in contact, on the side flanks of trenches 108, with dielectric layer 104 and layer 106. As an example, in the structure illustrated in FIG. 1, metal layer 110 does not coat the upper surface of dielectric layer 104 at the surface of trenches 108. Indeed, the latter is locally removed, for example by mechanical polishing, for example by chemical mechanical polishing (CMP), so that layers 110 are individualized in trenches 108. In the example of FIG. 1, metal layer 110 is in contact, at the bottom of trenches 108, with copper pads 102.

Metal layer 110 has, for example, a constant thickness on the side flanks and at the bottom of trenches 108. As an example, layer 110 has a thickness in the range from 5 nm to 30 nm, for example a thickness in the order of 15 nm. As an example, metal layer 110 is based on titanium, for example, based on titanium and nitride, for example on titanium silicon nitride (TiNSi).

As an example, electronic device 100 further comprises an insulating layer 112. Layer 112 coats, for example, the upper surface of metal layer 110. As an example, layer 110 is thus in contact, by its lower surface, with the upper surface of layer 110, on the side flanks of trenches 108 and at the bottom of trenches 108. As an example, insulating layer 112 further coats the upper surface of dielectric layer 104. Layer 112 is, for example, in contact, by its lower surface, with the upper surface of dielectric layer 104 at the surface of trenches 108. As an example, layer 112 is made of a dielectric material, for example a material having a high dielectric constant (high-k), that is, having a dielectric constant greater than that of silicon dioxide. As an example, layer 112 is made of hafnium oxide (HfO₂) or of alumina (Al₂O₃). Layer 112 has, for example, a constant thickness. As an example, layer 112 has a thickness in the range from 5 nm to 20 nm, for example a thickness in the order of 13 nm.

As an example, electronic device 100 further comprises a metal layer 114. Layer 114 for example coats the upper surface of layer 112. As an example, metal layer 114 is in contact, by its lower surface, with the upper surface of insulating layer 112 and, in particular, on the side flanks and at the bottom of trenches 108 and on the upper surface of layer 104 at the surface of trenches 108. As an example, layer 114 is made of titanium silicon nitride (TiNSi). Layer 114 has, for example, a constant thickness. As an example, layer 114 has a thickness in the range from 4 nm to 15 nm, for example a thickness in the order of 8 nm.

As an example, layer 114 is covered with a conductive layer 116. As an example, layer 116 is in contact, by its lower surface, with the upper surface of metal layer 114. For example, layer 116 covers layer 114 in trenches 108, thus filling them. As an example, layer 116 coats layer 114 at the surface of trenches 108. Layer 116 is, for example, made of titanium nitride (TiN) or made of tungsten (W).

In device 100, the assembly of metal layers 110, 114 and of insulating layer 112 forms a capacitor of metal-insulator-metal (MIM) type, for example, here, a three-dimensional (3D) MIM capacitor. In this example, layer 110 corresponds to a lower electrode of the capacitor and layer 114 corresponds to an upper electrode of the capacitor. As an example, a same device comprises a succession of a plurality of identical capacitors, formed side by side, for example a succession of seven capacitors, for example within the same pixel of the image sensor, or within a same memory cell. Within a same pixel or memory cell, the capacitors have, for example, a common upper electrode, corresponding to layer 114. Within a same pixel, or within a same memory cell, the capacitors have, for example, lower electrodes common and connected to one another, or individual and not connected to one another, depending, respectively, on their connection to a same pad 102 or to different pads 102.

As an example, device 100 comprises a succession of a plurality of pixels, or a plurality of memory cells, each comprising one or a plurality of capacitors.

The 3D capacitor is, for example, formed between two metal levels of an interconnection network formed on an already-structured wafer, that is, in the back end of line (BEOL) phase of the integrated circuit manufacturing process. As an example, 3D capacitor 102 is formed between a lower level, for example a metal level 3 or M3, represented in FIG. 1 by pads 102, and an upper level, for example a metal level 4 or M4, formed above layer 116.

In such a device 100, layer 110 is deposited in the trenches 108 formed in dielectric layer 104 and layer 106, while the latter emerge onto pads 102. Layer 110 is then formed in contact with pads 102 at the bottom of trenches 108. Layer 110 is deposited with a deposition method enabling to perform a highly conformal thickness deposition on the side flanks and at the bottom of trenches 108. Layer 110 is deposited with a method of atomic layer deposition (ALD).

During such a deposition, the structure is heated to a temperature higher than 350 ° C., for example in the order of 440 ° C., for more than one minute, for example for approximately 15 minutes. This heating causes an expansion of the copper of pads 102, and forms a bump on the surface of pads 102. A bump of this type may, by thermomechanical relaxation effects, during the lifetime of the device, detach from pad 102, forming, between pad 102 and layer 110, a hole cutting the electrical connection between pad 102 and layer 110.

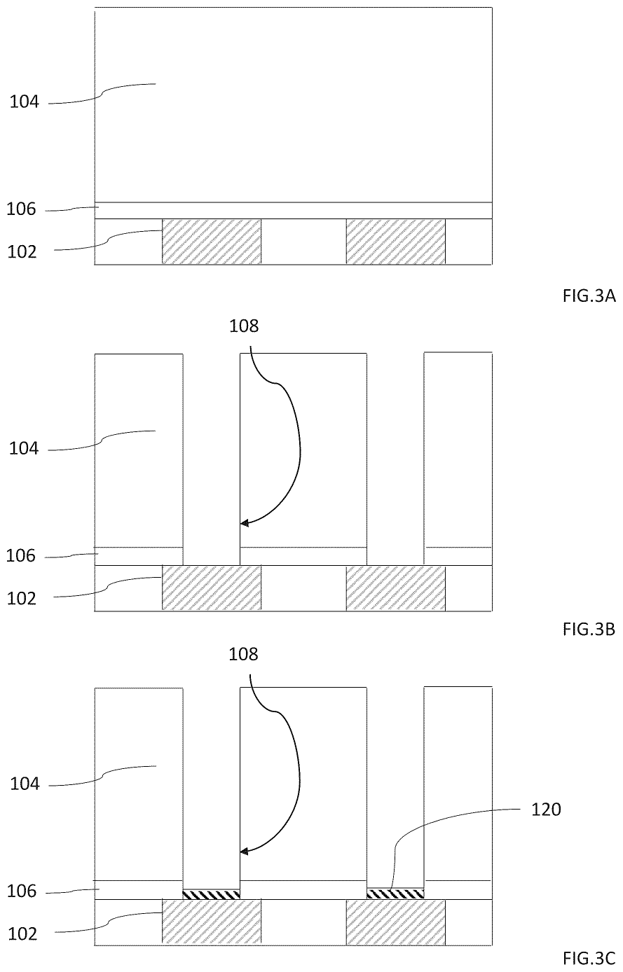

FIG. 2 is a cross-section view of an example of an electronic device 200 according to an embodiment.

The electronic device 200 shown in FIG. 2 is similar to the electronic device shown in FIG. 1, with the difference that it comprises, at the bottom of each trench 108, a conductive layer 120 between pad 102 and layer 110. In FIG. 2, conductive layer 120 is in contact, by its lower surface, with the upper surface of pad 102, and by its upper surface, with the lower surface of layer 110. Conductive layer 120 is, for example, made of a metallic material.

As an example, conductive layer 120 is made of tantalum nitride (TaN), of tantalum (Ta), or of a bilayer of tantalum nitride and tantalum. As an example, metal layer 110 is made of titanium silicon nitride (TiSiN) and conductive layer 120 is made of a selected one of: tantalum nitride (TaN), tantalum (Ta), or a tantalum nitride and tantalum bilayer. As an example, conductive layer 120 is a bilayer comprising a tantalum nitride layer and a tantalum layer. As an example, when it is made of TaN and/or of Ta, conductive layer 120 has a thickness lower than 20 nm, for example a thickness in the range from 3 nm to 15 nm, for example a range from 5 nm to 9 nm, for example a thickness in the order of 6.5 nm.

As a variant, conductive layer 120 is made of titanium nitride (TiN). As an example, metal layer 110 is made of titanium silicon nitride (TiSiN) and conductive layer 120 is made of titanium nitride (TiN). As an example, when it is made of titanium nitride, layer 120 has a thickness lower than 20 nm, for example a thickness in the range from 3 nm to 9 nm, for example a thickness in the order of 5 nm.

In the embodiment of FIG. 2, metal layer 110 has a thickness in the range from 5 nm to 25 nm, for example a range from 5 nm to 15 nm, for example a thickness in the order of 10 nm.

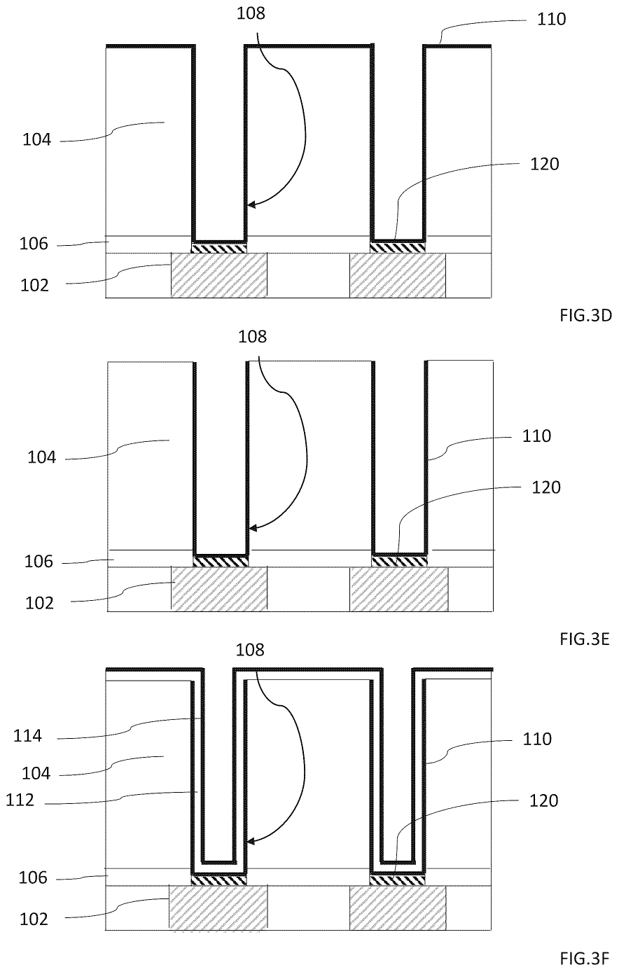

FIGS. 3A to 3F each show are a cross-section view of a structure obtained at the end of a step of a method of manufacturing the electronic device illustrated in FIG. 2.

FIG. 3A is a cross-section view of an initial structure comprising layers 104 and 106 formed on metal pads 102.

FIG. 3B is a cross-section view of a structure obtained at the end of a step of forming of trenches 108 in the structure illustrated in FIG. 3A.

More specifically, during this step, trenches 108 are formed in layer 104 and layer 106 from the upper surface of layer 104. Trenches 108 are, for example, formed in such a way as to emerge onto the upper surface of pads 102, thus exposing the upper surface of pads 102. As an example, each trench 108 is formed opposite a pad 102. Trenches 108 are, for example, formed by etching.

FIG. 3C shows a cross-section view of a structure obtained after a step of forming metal layer 120 in the structure shown in FIG. 3B.

More particularly, during this step, layer 120 is formed at the bottom of each of trenches 108 in contact with the upper surface of pads 102.

Layer 120 is, during this step, deposited with a thickness, for example, lower than 20 nm with a rapid deposition method, that is, of a duration shorter than two minutes, or at low temperature, that is, requiring a heating of the structure below 200 ° C.

According to a first implementation mode, layer 120 is made of TaN and Ta (TaN/Ta) and is deposited according to a method of physical vapor deposition (PVD).

In a first stage, in this implementation mode, a first part of TaN layer 120 is deposited. A second part of Ta layer 120 is deposited in a second stage. In this implementation mode, both parts of layer 120 are formed at the bottom of trench 108. During this step, layer 120 also forms on the side flanks of trench 108 with a thickness lower than the thickness of layer 120 at the bottom of trench 108 (this structure is not explicitly shown in the figure). As an example, at the bottom of trench 108, the part of layer 120 made of TaN has a thickness in the order of 2.5 nm and the part of layer 120 made of Ta has a thickness in the order of 4 nm. As an example, layer 120 is deposited with a total deposition time in the order of ten seconds. As an example, layer 120 is deposited at room temperature, for example at a temperature in the range from 15 ° C and 30 ° C.

As a variant, layer 120 is made of Ta only, of TaN only, or of Ta/TaN.

According to a second implementation mode, layer 120 is made of titanium nitride (TiN) and is deposited by a method of chemical vapor deposition (CVD). In this implementation mode, layer 120 is formed at the bottom of trench 108. During this step, layer 120 is also formed on the side flanks of trench 108 with a thickness substantially identical to the thickness of layer 120 at the bottom of trench 108 (this structure is not explicitly shown in the figure). As an example, layer 120 is deposited with a total deposition time in the order of sixteen seconds. As an example, layer 120 is deposited at a temperature in the order of 400 ° C. As an example, in this implementation mode, the time required to stabilize the temperature for the deposition is in the order of one minute.

FIG. 3D shows a cross-section view of a structure obtained at the end a step of deposition of metal layer 110 in the structure shown in FIG. 3C.

More particularly, during this step, layer 110 is formed at the bottom and on the side flanks of trenches 108. Further, during this step, layer 110 is formed on the upper surface of dielectric layer 104 at the surface of trenches 108.

During this step, layer 110 is thus formed, at the bottom of trenches 108, in contact with layer 120. Further, during this step, layer 110 is formed, on the side flanks of trenches 108, in contact with dielectric layer 104 and layer 106 or, if applicable, with layer 120 (when the latter is formed on the side flanks of trenches 108). Further, during this step, layer 110 is formed on the surface of trenches 108 in contact with dielectric layer 104.

Layer 110 is, for example, deposited by a conformal deposition method, for example by atomic layer deposition (ALD).

As an example, layer 110 is deposited with a total deposition time in the order of fifteen minutes. As an example, layer 120 is deposited at a temperature in the order of 440 ° C. As an example, in this implementation mode, the time required to stabilize the temperature for the deposition is in the order of one minute.

FIG. 3E shows a cross-section view of a structure obtained at the end of a step of polishing of the upper surface of the structure shown in FIG. 3D.

More particularly, during this step, the portions of layer 110 formed on the surface of trenches 108 are removed. The partial removal of layer 110 is performed, for example, by mechanical polishing, for example by chemical-mechanical polishing (CMP).

FIG. 3F shows a cross-section view of a structure obtained at the end of a step of deposition of insulating layer 112 and metal layer 114 on the upper surface of the structure shown in FIG. 3E.

More particularly, during this first step in a first stage, insulating layer 112 is formed in contact with layer 110 on the upper surface of the structure illustrated in FIG. 3E.

In a second stage, metal layer 114 is formed on top of and in contact with the upper surface of layer 112.

An advantage of the present embodiment is that it allows, at the surface of pad 102 and in contact therewith, the deposition of a conductive layer 120, within a shorter time or at a lower temperature than what is required for the deposition of layer 110.

Another advantage of the present embodiment is that conductive layer 120 plays the role of a barrier layer, which enables to limit the expansion of the copper of pads 102 during the deposition of layer 110.

Still another advantage of the present embodiment is that it enables to limit the risk of protrusions appearing on the surface of pads 102.

Various embodiments and variants have been described. Those skilled in the art will understand that certain features of these various embodiments and variants could be combined, and other variants will become apparent to those skilled in the art.

In particular, although the use of a conductive layer 120 in a 3D MIM capacitor structure has been described hereabove, such a layer may more generally be used between any copper layer topped with a layer deposited at high temperature for a significant time, for example by ALD.

Further, there has been described that layer 120 may be made of titanium nitride or of tantalum and tantalum nitride. In practice, layer 120 may be made of materials other than those mentioned and in particular of any other material deposited rapidly, for example within a time shorter than two minutes, and/or at low temperature, for example below 200 ° C.

Further, there has been described that metal layer 110 may be made of titanium silicon nitride. In practice, layer 110 may be made of any other material, for example made of any other conductive material deposited by ALD.

Finally, the practical implementation of the modes of realization and variants described is within the reach of the person skilled in the art on the basis of the functional indications given above.

1. An electronic device, comprising:
a copper pad;
a first dielectric layer on the copper pad, wherein the dielectric layer includes a trench extending through the dielectric layer and emerging onto the copper pad;
a first metal layer on side flanks and at a bottom of the trench; and
a conductive layer forming an interface at the bottom of the trench between the copper pad and the first metal layer, the conductive layer being in contact, by its lower surface, with an upper surface of the copper pad, and being in contact, by its upper surface, with a lower surface of the first metal layer.

2. The device according to claim 1, wherein the conductive layer has a thickness smaller than 20 nm.

3. The device according to claim 1, wherein the first metal layer is made of titanium silicon nitride and wherein the conductive layer is made of one of: titanium nitride, tantalum, tantalum nitride, or a tantalum nitride and tantalum bilayer.

4. The device according to claim 1, wherein the first metal layer corresponds to a first electrode of a three-dimensional capacitor.

5. The device according to claim 4, wherein the three-dimensional capacitor is a metal-insulator-metal capacitor comprising a second dielectric layer over the first metal layer, and a second metal layer over said second dielectric layer, wherein the second dielectric layer is in contact, by its lower surface, with the first metal layer, and in contact, by its upper surface, with the second metal layer.

6. The device according to claim 1, wherein the conductive layer entirely covers the copper pad exposed at the bottom of the trench.

7. The device according to claim 1, wherein the first dielectric layer is separated from the copper pad by a nitride passivation layer.

8. A method of manufacturing an electronic device, comprising the successive steps of:
forming a trench extending through a first dielectric layer to emerge onto a copper pad;
depositing a conductive layer at a bottom of the trench; and
depositing a first metal layer on side flanks and at a bottom of the trench;
wherein the conductive layer forms an interface between the copper pad and the first metal layer, the conductive layer being in contact, by its lower surface, with an upper surface of the copper pad, and being in contact, by its upper surface, with a lower surface of the first metal layer.

9. The method according to claim 8, wherein the conductive layer has a thickness smaller than 20 nm.

10. The method according to claim 8, wherein depositing the first metal layer comprises depositing by an atomic layer deposition method and wherein depositing the conductive layer comprises depositing by one of: a physical vapor deposition method or a chemical vapor deposition method.

11. The method according to claim 8, wherein depositing the conductive layer comprises depositing the conductive layer also on the side flanks of the trench.

12. The method according to claim 8, wherein depositing the conductive layer comprises completing deposition within less than two minutes.

13. The method according to claim 8, wherein depositing the conductive layer comprises depositing at a temperature lower than 200 °C.

14. The method according to claim 8, wherein depositing the conductive layer comprises depositing within less than two minutes and at a temperature lower than 200 °C.

15. The method according to claim 8, further comprising:
forming passivation layer formed between the dielectric layer and the copper pad; and
wherein forming the trench comprises extending the trench through the passivation layer to reach the copper pad.
